(19) United States
(12) Patent Application Publication
(10) Pub. No.: US 2012/0037216 A1
(43) Pub. Date: Feb. 16, 2012

(54) CONDUCTIVE PASTE AND ELECTRONIC DEVICE AND SOLAR CELL INCLUDING AN ELECTRODE FORMED USING THE CONDUCTIVE PASTE

(75) Inventors: Se-Yun KIM, Seoul (KR); Eun-Sung LEE, Seoul (KR); Sang-Soo JEE, Hwaseong-si (KR); Sang-Mock LEE, Yongin-si (KR)

(73) Assignee: SAMSUNG ELECTRONICS CO., LTD., Suwon-si (KR)

(21) Appl. No.: 13/021,535

(22) Filed: Feb. 4, 2011

(30) Foreign Application Priority Data
Aug. 13, 2010 (KR) 10-2010-0078344

(51) Int. Cl. H01L 31/0224; H01B 1/02

(52) U.S. Cl. 136/252; 252/512; 252/514; 252/513; 252/515

(57) ABSTRACT

A conductive paste including a conductive powder, a metallic glass, and an organic vehicle, wherein the metallic glass includes an alloy of at least two metals selected from a first metal having a low resistivity, a second metal which forms a solid solution with the conductive powder, a third metal which extends a supercooled liquid region of the metallic glass, or a fourth metal having a higher standard free energy of formation of oxide than a standard free energy of formation of oxide of the first, the second, and third metals.

### CROSS-REFERENCE TO RELATED APPLICATION

This application claims priority to Korean Patent Application No. 10-2010-0078344, filed on Aug. 13, 2010, and all the benefits accruing therefrom under 35 U.S.C. §119, the content of which in its entirety is herein incorporated by reference.

### BACKGROUND

1. Field

This disclosure relates to a conductive paste, and an electronic device and a solar cell including an electrode formed using the conductive paste.

2. Description of the Related Art

A solar cell is a photoelectric conversion device that transforms solar energy into electrical energy. Solar cells have attracted much attention as a potentially infinite and essentially pollution-free next generation energy source.

A solar cell includes p-type and n-type semiconductors. When an electron-hole pair (“EHP”) is produced by light absorbed in a photoactive layer of the semiconductors, the solar cell produces electrical energy by transferring electrons and holes to the n-type and p-type semiconductors, respectively, and then collects the electrons and the holes in respective electrodes of the solar cell.

A solar cell desirably has as high efficiency as possible for producing electrical energy from solar energy. In order to improve this efficiency, the solar cell desirably absorbs light with minimal loss, so that it may produce as many electron-hole pairs as possible, and then collect the produced charges without significant loss.

An electrode may be fabricated using a deposition method, which may include a complicated process, have a high cost, and can take a long time. Accordingly, a simplified process, such as screen printing a conductive paste including a conductive material, has been suggested. However, an electrode formed using a conductive paste may have low conductivity because of a glass frit included in a conductive paste. Thus there remains a need for an improved conductive paste.

### SUMMARY

An aspect of this disclosure provides a conductive paste which is capable of improving conductivity of an electrode.

Another aspect of this disclosure provides an electronic device including an electrode including the fired conductive paste.

Yet another aspect of this disclosure provides a solar cell including an electrode including the fired conductive paste.

According to an aspect of this disclosure, disclosed is a conductive paste including a conductive powder, a metallic glass, and an organic vehicle. Herein, the metallic glass includes an alloy of at least two metals selected from a first metal having a low resistivity, a second metal which forms a solid solution with the conductive powder, a third metal which extends a supercooled liquid region of the metallic glass, and a fourth metal having a higher standard free energy of formation of oxide than a standard free energy of formation of oxide of each of the first, the second, and the third metals when present.

The first metal may have resistivity of less than about 100 microohm-centimeters (“μΩcm”).

The first metal may have resistivity of less than about 15 μΩcm.

The first metal may beat least one selected from silver (Ag), copper (Cu), gold (Au), aluminum (Al), calcium (Ca), beryllium (Be), magnesium (Mg), sodium (Na), molybdenum (Mo), tungsten (W), tin (Sn), zinc (Zn), nickel (Ni), potassium (K), lithium (Li), iron (Fe), palladium (Pd), platinum (Pt), rubidium (Rb), chromium (Cr), and strontium (Sr).

The second metal may have a heat of mixing with the conductive powder of less than 0 kJ/mol.

The conductive powder may include silver (Ag), and the second metal may be at least one selected from lanthanum (La), cerium (Ce), praseodymium (Pr), promethium (Pm), samarium (Sm), lutetium (Lu), yttrium (Y), neodymium (Nd), gadolinium (Gd), terbium (Tb), dysprosium (Dy), holmium (Ho), erbium (Er), thulium (Tm), thorium (Th), calcium (Ca), scandium (Sc), barium (Ba), ytterbium (Yb), strontium (Sr), europium (Eu), zirconium (Zr), lithium (Li), hafnium (Hf), magnesium (Mg), phosphorus (P), arsenic (As), palladium (Pd), gold (Au), plutonium (Pu), gallium (Ga), germanium (Ge), aluminum (Al), zinc (Zn), antimony (Sb), silicon (Si), tin (Sn), titanium (Ti), cadmium (Cd), indium (In), platinum (Pt), and mercury (Hg).

The third metal may reduce the glass transition temperature (“Tg”) of the metallic glass or increase the crystallization temperature (“Tc”) of the metallic glass.

The metallic glass may include copper (Cu) and zirconium (Zr), and the third metal may include at least one selected from aluminum (Al), silver (Ag), nickel (Ni), titanium (Ti), iron (Fe), and hafnium (Hf).

The third metal may be included in an amount of about 10 atomic percent (at %) or less, based on the total amount of the metallic glass.

The metallic glass may have a supercooled liquid region of about 5° C. to about 200° C.

The fourth metal may have an absolute value of a Gibbs free energy of metal oxide formation greater than an absolute value of a Gibbs free energy of metal oxide formation of each of the first, the second, and the third metals, if present.

The fourth metal may have an absolute value of a Gibbs free energy of metal oxide formation of about 100 kiloJoules per mole (kJ/mol) or greater.

The conductive powder, the metallic glass, and the organic vehicle may be included in an amount of about 30 to about 98 weight percent (wt %), about 1 to about 50 wt %, and about 69 to about 1 wt %, respectively, based on the total weight of the conductive paste, respectively.

According to another aspect of the disclosure, an electronic device includes an electrode including a fired conductive paste including a conductive powder, a metallic glass, and an organic vehicle. Herein, the metallic glass is an alloy of at least two metals selected from a first metal having a low resistivity, a second metal which forms a solid solution with the conductive powder, a third metal which extends a supercooled liquid region of the metallic glass, and a fourth metal having a higher standard free energy of formation of oxide than a standard free energy of formation of oxide of each of the first, the second, and the third metals when present.

The first metal may have resistivity of less than about 100 μΩcm, and the second metal may have a heat of mixing with the conductive powder of less than 0 kJ/mol.

The third metal may reduce a glass transition temperature (“Tg”) of the metallic glass or increase the crystallization temperature (“Tc”) of the metallic glass, and the fourth metal may have an absolute value of a Gibbs free energy of metal oxide formation greater than an absolute value of a Gibbs free energy of metal oxide formation of each of the first, the second, and the third metals when present.

According to another aspect of the disclosure, a solar cell includes a semiconductor layer and an electrode electrically connected with the semiconductor layer and including a fired conductive paste including a conductive powder, a metallic glass, and an organic vehicle, wherein, the metallic glass is an alloy of at least two metals selected from a first metal having a low resistivity, a second metal which forms a solid solution with the conductive powder, a third metal which extends a supercooled liquid region of the metallic glass, and a fourth metal having a higher standard free energy of formation of oxide than a standard free energy of formation of oxide of each of the first, the second, and the third metals when present.

The first metal may have resistivity of less than about 100 μΩcm, and the second metal may have a heat of mixing with the conductive powder of less than 0 kJ/mol.

The first metal may be at least one selected from silver (Ag), copper (Cu), gold (Au), aluminum (Al), calcium (Ca), beryllium (Be), magnesium (Mg), sodium

(Na), molybdenum (Mo), tungsten (W), tin (Sn), zinc (Zn), nickel (Ni), potassium (K), lithium (Li), iron (Fe), palladium (Pd), platinum (Pt), rubidium (Rb), chromium (Cr), and strontium (Sr).

The conductive powder may include silver (Ag), and the second metal may be at least one selected from lanthanum (La), cerium (Ce), praseodymium (Pr), promethium (Pm), samarium (Sm), lutetium (Lu), yttrium (Y), neodymium (Nd), gadolinium (Gd), terbium (Tb), dysprosium (Dy), holmium (Ho), erbium (Er), thulium (Tm), thorium (Th), calcium (Ca), scandium (Sc), barium (Ba), ytterbium (Yb), strontium (Sr), europium (Eu), zirconium (Zr), lithium (Li), hafnium (Hf), magnesium (Mg), phosphorus (P), arsenic (As), palladium (Pd), gold (Au), plutonium (Pu), gallium (Ga), germanium (Ge), aluminum (Al), zinc (Zn), antimony (Sb), silicon (Si), tin (Sn), titanium (Ti), cadmium (Cd), indium (In), platinum (Pt), and mercury (Hg).

The third metal may reduce the glass transition temperature (“Tg”) of the metallic glass or increase a crystallization temperature (“Tc”) of the metallic glass, and the fourth metal may have an absolute value of a Gibbs free energy of metal oxide formation greater than an absolute value of a Gibbs free energy of metal oxide formation of each of the first, the second, and the third metals.

According to yet another aspect of the disclosure, a solar cell includes a semiconductor layer, an electrode including a conductive material and electrically connected with the semiconductor layer, and a buffer layer contacting the semiconductor layer and the electrode. Herein, the buffer layer may include an alloy of at least two metals selected from a first metal having a low resistivity, a second metal which forms a solid solution with the conductive powder, a third metal which extends a supercooled liquid region of a metallic glass of the buffer layer, and a fourth metal having a higher standard free energy of formation of oxide than a standard free energy of formation of oxide of each of the first, the second, and the third metals if present.

The buffer layer may further include a crystallized conductive material.

The conductive material may be included in at least one of the semiconductor layer and the buffer layer.

The first metal may have resistivity of less than about 100 μΩcm, and the second metal may have a heat of mixing with the conductive powder of less than 0 kJ/mol.

The first metal may be at least one selected from silver (Ag), copper (Cu), gold (Au), aluminum (Al), calcium (Ca), beryllium (Be), magnesium (Mg), sodium (Na), molybdenum (Mo), tungsten (W), tin (Sn), zinc (Zn), nickel (Ni), potassium (K), lithium (Li), iron (Fe), palladium (Pd), platinum (Pt), rubidium (Rb), chromium (Cr), and strontium (Sr).

The conductive powder may include silver (Ag), and the second metal may be at least one selected from lanthanum (La), cerium (Ce), praseodymium (Pr), promethium (Pm), samarium (Sm), lutetium (Lu), yttrium (Y), neodymium (Nd), gadolinium (Gd), terbium (Tb), dysprosium (Dy), holmium (Ho), erbium (Er), thulium (Tm), thorium (Th), calcium (Ca), scandium (Sc), barium (Ba), ytterbium (Yb), strontium (Sr), europium (Eu), zirconium (Zr), lithium (Li), hafnium (Hf), magnesium (Mg), phosphorus (P), arsenic (As), palladium (Pd), gold (Au), plutonium (Pu), gallium (Ga), germanium (Ge), aluminum (Al), zinc (Zn), antimony (Sb), silicon (Si), tin (Sn), titanium (Ti), cadmium (Cd), indium (In), platinum (Pt), and mercury (Hg).

The third metal may reduce the glass transition temperature (“Tg”) of the metallic glass or increase a crystallization temperature (“Tc”) of the metallic glass, and the fourth metal may have an absolute value of a Gibbs free energy of metal oxide formation greater than an absolute value of a Gibbs free energy of metal oxide formation of each of the first, the second, and the third metals, if present.

### BRIEF DESCRIPTION OF THE DRAWINGS

The above and other aspects, advantages and features of this disclosure will become more apparent by describing in further detail exemplary embodiments thereof with reference to the accompanying drawings, in which:

FIGS. 1 to 3 are a schematic diagram of an embodiment of heat treating a conductive powder and a metallic glass on a semiconductor substrate;

FIGS. 4A to 4C are a schematic diagram showing an expanded view of region A of FIG. 3;

FIG. 5 is a cross-sectional view of an embodiment of a solar cell; and

FIG. 6 is a cross-sectional view of another embodiment of a solar cell.

### DETAILED DESCRIPTION

Exemplary embodiments will hereinafter be described in further detail with reference to the accompanying drawings, in which various embodiments are shown. This disclosure may, however, be embodied in many different forms and should not be construed as limited to the exemplary embodiments set forth herein.

As used herein, the term “and/or” includes any and all combinations of one or more of the associated listed items. It will be understood that, although the terms “first,” “second,” “third” etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, “a first element,” “component,” “region,” “layer,” or “section” discussed below could be termed a second element, component, region, layer, or section without departing from the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. The term “at least one” means a combination comprising one or more of the listed components may be used.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

“Alkyl” means a straight or branched chain saturated aliphatic hydrocarbon having 1 to 12 carbon atoms, more specifically 1 to 6 carbon atoms.

Herein, the term ‘metal’ refers to a metal and a semimetal.

First, disclosed is a conductive paste.

The conductive paste according to an embodiment includes a conductive powder, a metallic glass, and an organic vehicle.

The conductive powder may comprise at least one metal or alloy selected from an aluminum (Al)-containing metal such as aluminum or an aluminum alloy, a silver (Ag)-containing metal such as silver or a silver alloy, a copper (Cu)-containing metal such as copper (Cu) or a copper alloy, a nickel (Ni)-containing metal such as nickel (Ni) or a nickel alloy. However, the conductive powder is not limited thereto but may include other metals, an additive that is not the metal or alloy.

The conductive powder may have a size (e.g., average largest particle size) ranging from about 0.1 to 50 micrometers (μm), specifically about 0.5 to about 40 μm, more specifically about 1 to about 30 μm. Particles of the conductive powder may be irregular, or have a spherical, rod-like, or plate-like shape.

The metallic glass includes an alloy having a disordered atomic structure including two or more metals. The metallic glass may be an amorphous metal. The metallic glass may have about 50 to about 100 weight percent (“wt %”), specifically about 70 to about 100 wt %, more specifically about 90 to about 100 wt % amorphous content, based on a total weight of the metallic glass. Because the metallic glass has a low resistivity, and thus is different from an insulating glass such as a silicate, it may be considered to be an electrical conductor at a voltage and a current of a solar cell.

The metallic glass is an alloy of at least two metals selected from a first metal which has a low resistivity, a second metal which is capable of forming a solid solution with the conductive powder, a third metal which is capable of extending a supercooled liquid region of the metallic glass, or a fourth metal having a higher standard free energy of formation of oxide than each of the first, the second, or the third metals when the first, second, or third metals is present in the metallic glass.

The first metal, which has a low resistivity, may substantially determine the conductivity of the metallic glass. The first metal may have a resistivity of less than about 100 microohm-centimeters (μΩcm), specifically about 0.001 to about 90 μΩcm, more specifically about 0.01 to about 50 μΩcm. In an embodiment, the first metal may have resistivity of less than about 15 μΩcm.

The first metal may be, for example, at least one selected from silver (Ag), copper (Cu), gold (Au), aluminum (Al), calcium (Ca), beryllium (Be), magnesium (Mg), sodium (Na), molybdenum (Mo), tungsten (W), tin (Sn), zinc (Zn), nickel (Ni), potassium (K), lithium (Li), iron (Fe), palladium (Pd), platinum (Pt), rubidium (Rb), chromium (Cr), and strontium (Sr).

The second metal is capable of forming a solid solution with the conductive powder when present in the metallic glass.

When the metallic glass is heated to a temperature which is higher than a glass transition temperature (Tg) of the metallic glass, it may be soft, like glass, and show a liquid-like behavior. Herein, because the metallic glass includes a second metal which is capable of forming a solid solution with the conductive powder, the conductive powder may diffuse into the softened metallic glass.

For example, when the conductive paste including the metallic glass is disposed on a semiconductor substrate to form an electrode for a solar cell, the metallic glass becomes soft during the heat treatment. In addition, during the heat treatment, particles of the conductive powder form a solid solution with the second metal when it is included in the metallic glass, and thus the particles of the conductive powder diffuse into the softened metallic glass.

Finally, the particles of the conductive powder may diffuse into the semiconductor substrate through the softened metallic glass when the second metal is present. Accordingly, after cooling, crystallized particles of the conductive powder are produced at or near the surface of the semiconductor substrate in a large amount. In this way, the crystallized particles of the conductive powder formed at or near the surface of the semiconductor substrate may improve the transfer of charges produced in the semiconductor substrate by solar cell, thereby improving efficiency of the solar cell.

The second metal which is capable of forming a solid solution with a conductive powder may be selected from metals having a heat of mixing (“Hm”) of less than 0 kiloJoules per mole (kJ/mol), specifically less than −0.1 kJ/mol, more specifically less than −0.5 kJ/mol with the conductive powder.

For example, when the conductive powder includes silver (Ag), the second metal may include, for example, lanthanum (La), cerium (Ce), praseodymium (Pr), promethium (Pm), samarium (Sm), lutetium (Lu), yttrium (Y), neodymium (Nd), gadolinium (Gd), terbium (Tb), dysprosium (Dy), holmium (Ho), erbium (Er), thulium (Tm), thorium (Th), calcium (Ca), scandium (Sc), barium (Ba), ytterbium (Yb), strontium (Sr), europium (Eu), zirconium (Zr), lithium (Li), hafnium (Hf), magnesium (Mg), phosphorus (P), arsenic (As), palladium (Pd), gold (Au), plutonium (Pu), gallium(Ga), germanium (Ge), aluminum (Al), zinc (Zn), antimony (Sb), silicon (Si), tin (Sn), titanium (Ti), cadmium (Cd), indium(In), platinum (Pt), or mercury (Hg). The heat of mixing of representative combinations of a second metal with Ag are listed in the following Table 1.

TABLE 1

| | Hm | | Hm | | Hm |
|---|---|---|---|---|---|
| X—Ag | (kJ/mol) | X—Ag | (kJ/mol) | X—Ag | (kJ/mol) |
| La—Ag | −30 | Nd—Ag | −29 | Th—Ag | −29 |
| Ce—Ag | −30 | Gd—Ag | −29 | Ca—Ag | −28 |
| Pr—Ag | −30 | Tb—Ag | −29 | Sc—Ag | −28 |
| Pm—Ag | −30 | Dy—Ag | −29 | Ba—Ag | −28 |
| Sm—Ag | −30 | Ho—Ag | −29 | Yb—Ag | −28 |
| Lu—Ag | −30 | Er—Ag | −29 | Sr—Ag | −27 |
| Y—Ag | −29 | Tm—Ag | −29 | Eu—Ag | −27 |
| Zr—Ag | −20 | Au—Ag | −6 | Si—Ag | −3 |
| Li—Ag | −16 | Pu—Ag | −6 | Sn—Ag | −3 |
| Hf—Ag | −13 | Ga—Ag | −5 | Ti—Ag | −2 |
| Mg—Ag | −10 | Ge—Ag | −5 | Cd—Ag | −2 |
| P—Ag | −10 | Al—Ag | −4 | In—Ag | −2 |
| As—Ag | −8 | Zn—Ag | −4 | Pt—Ag | −1 |
| Pd—Ag | −7 | Sb—Ag | −4 | Hg—Ag | −1 |

The third metal that may be present in the metallic glass is a metal which is capable of extending the supercooled liquid region of the metallic glass.

Herein, the supercooled liquid region of a metallic glass is a temperature region between a glass transition temperature (“Tg”) and a crystallization temperature (“Tc”) of the metallic glass. In the supercooled liquid region, the metallic glass has relatively low viscosity and shows a liquid-like behavior. The glass transition temperature may be about 50° C. to about 700° C., specifically about 75° C. to 1.0 about 650° C., more specifically about 100° C. to about 600° C. Also, the crystallization temperature may be about 60° C. to about 720° C., specifically about 85° C. to about 670° C., more specifically about 110° C. to about 620° C.

The third metal may reduce the glass transition temperature (“Tg”) of the metallic glass and increase the crystallization temperature (“Tc”) of the metallic glass, and thus can extend the supercooled liquid region in which the metallic glass has a liquid-like behavior. The third metal may reduce the Tg of the metallic glass by about 1° C. to about 300° C., specifically about 10° C. to about 250° C., more specifically about 20° C. to about 200° C. Also, the third metal may increase the Tc of the metallic glass by about 1° C. to about 300° C., specifically about 10° C. to about 250° C., more specifically about 20° C. to about 200° C.

Thus the supercooled liquid region of the metallic glass is greater with the third metal than without the third metal.

While not wanting to be bound by theory, it believed that when the third metal is included in the metallic glass, it hampers interaction of other metal components included therein and thus the metallic glass shows a liquid-like behavior at a lower temperature. Alternatively, when the third metal is included in the metallic glass, it hampers interaction of other metal components and suppresses nucleus formation, and thus delays crystallization and thereby increases the crystallization temperature (“Tc”).

In the supercooled liquid region, which is a temperature region between glass transition temperature (Tg) and crystallization temperature (Tc), the metallic glass shows a liquid-like behavior and can wet a lower layer (e.g., lower semiconductor layer) of a solar cell or other electronic device, e.g., semiconductor substrate. Herein, when the supercooled liquid region is extended, the conductive paste may improve wetting properties towards a substrate, such as a semiconductor substrate.

For example, when a conductive paste including the metallic glass is applied on a semiconductor substrate to fabricate an electrode for a solar cell, the larger the supercooled liquid region of the softened metallic glass on the semiconductor substrate, the better the conductive paste wets the semiconductor substrate. The improved wetting properties of the conductive paste may allow the conductive powder, which diffuses into the softened metallic glass, to permeate into a larger area of the semiconductor substrate. Accordingly, the electrode disposed on the semiconductor substrate may have better contact (e.g., electrical contact) with the semiconductor substrate, thereby improving adherence therebetween and providing a larger or improved conductive path through which charges produced in the semiconductor substrate by solar light may transport. As a result, the electrode may improve efficiency of a solar cell.

The extended supercooled liquid region of the metallic glass may range from about 5° C. to about 200° C., specifically about 10° C. to about 180° C., more specifically about 20° C. to about 160° C., that is having a span of about 5° C. to about 200° C., specifically about 10° C. to about 180° C., more specifically about 20° C. to about 160° C. Thus when the third metal is included in the metallic glass, a supercooled region of the metallic glass may be about 5° C. to about 200° C., specifically about 10° C. to about 180° C., more specifically about 20° C. to about 160° C. Also the supercooled region may be within a temperature range of about 100° C. to about 800° C., specifically about 150° C. to about 750° C., more specifically about 200° C. to about 700° C.

The following Table 2 shows that when a metallic glass including copper (Cu) or palladium (Pd), for example as a first metal, zirconium (Zr), as a second metal for example, and aluminum (Al), silver (Ag), nickel (Ni), titanium (Ti), iron (Fe) and/or hafnium (Hf) as a third metal, the metallic glass has a larger supercooled liquid region.

TABLE 2

| | Glass | Crystal- | Supercooled |
|---|---|---|---|
| | transition | lization | liquid |
| | temperature | temperature | region |
| | (Tg, K) | (Tc, K) | (ΔTx, K) |
| Cu₅₀Zr₅₀ | 675 | 724 | 49 |
| Cu₅₄Zr₂₂Ni₆Ti₁₈ | 712 | 769 | 57 |
| Cu₄₈Zr₄₈Al₄ | 688 | 756 | 68 |
| Cu₄₇Zr₄₇Al₆ | 691 | 770 | 79 |
| Cu₅₀Zr₄₃Al₇ | 731 | 792 | 61 |
| Cu₄₆Zr₄₆Al₈ | 696 | 789 | 93 |
| Cu₄₅Zr₄₅Al₁₀ | 710 | 787 | 77 |
| Cu₄₅Zr₄₅Ag₁₀ | 683 | 756 | 73 |
| Cu₄₈Zr₄₈Al₂Ag₂ | 677 | 742 | 65 |
| Cu₄₆Zr₄₆Al₄Ag₄ | 686 | 767 | 81 |
| Cu₄₇Zr₄₅Al₄Ag₄ | 688 | 770 | 82 |
| Cu₄₈Zr₄₄Al₄Ag₄ | 692 | 779 | 87 |
| Cu₄₉Zr₄₃Al₄Ag₄ | 694 | 780 | 86 |
| Cu₅₀Zr₄₂Al₄Ag₄ | 703 | 784 | 81 |
| Cu₄₅Zr₄₅Al₅Ag₅ | 697 | 783 | 86 |
| Cu₄₄Zr₄₄Al₆Ag₆ | 698 | 790 | 92 |
| Cu₃₀Zr₄₈Al₈Ag₈Ni₆ | 688 | 779 | 91 |
| Cu₃₄Zr₄₈Al₈Ag₈Ni₂ | 683 | 799 | 116 |
| Cu₂₆Zr₄₈Al₈Ag₈Ni₁₀ | 692 | 768 | 76 |
| Cu_{22.8}Zr_{61.4}Al_{9.9}Ag₁Fe_{4.95} | 656 | 753 | 97 |
| Cu₃₄Zr₄₈Al₈Ag₈Fe₂ | 705 | 806 | 101 |
| Cu₃₆Zr₄₆Al₈Ag₈Hf₂ | 692 | 794 | 102 |
| Cu₃₆Zr₄₂Al₈Ag₈Hf₆ | 695 | 796 | 101 |
| Cu₃₄Zr₄₈Al₈Ag₈Pd₂ | 699 | 794 | 95 |
| Cu₃₀Zr₄₈Al₈Ag₈Pd₆ | 709 | 796 | 87 |

The third metal may be included in an amount of about 10 atomic percent (at %) or less, specifically about 5 at % or less, more specifically about 0.1 to about 10 at %, or about 1 to about 8 at %, based on the total amount of the metallic glass. When it is included within the foregoing range, a metallic glass may include the other components in a sufficient amount and thus have an extended supercooled liquid region and improved solid solubility with the conductive powder, and thus provide sufficient conductivity and oxidation resistance.

The fourth metal which may be present in the metallic glass has a higher oxidation property (e.g., standard free energy of formation of oxide) than any other components included in the metallic glass, and thus, may be oxidized before the other components of the metallic glass, thereby preventing their oxidation. The fourth metal may have a standard free energy of formation of oxide at least about 0.1 electron volt (eV), specifically at least about 0.3 eV, more specifically at least about 0.5 eV, or at least about 1 eV greater than a standard free energy of formation of oxide of each of the first, the second, or the third metals.

When a conductive paste including the metallic glass is processed in air, it may be exposed to oxygen in the air. If the first metal is oxidized, a conductive paste may have sharply deteriorated conductivity. When the second metal is oxidized, a conductive paste may have decreased solid solubility. When the third metal is oxidized, a metallic glass may have a decreased supercooled liquid region. Thus oxidation of any of the first, the second, or the third metals is undesirable.

Accordingly, when a metallic glass includes the fourth metal having a higher oxidation potential than each of the first, the second, and the third metals, the fourth metal is first oxidized and forms a stable oxide layer on the surface of the metallic glass. The oxide layer substantially or effectively prevents oxidation of other components, such as the first, the second, and the third metals therein. Furthermore, degradation of the properties of the conductive paste due to other components in the metallic glass, such as oxides of the first, the second, or the third metals, may be prevented.

The fourth metal may have a larger absolute value of a Gibbs Free Energy of metal oxide formation)(ΔG_{f}⁰) than an absolute value of a Gibbs Free Energy of metal oxide formation of each of the first, the second, and the third metals. The larger the absolute value of the Gibbs free energy of metal oxide formation a metal has, the easier it may be oxidized. The fourth metal may have an absolute value of a Gibbs Free Energy of metal oxide formation of more than about 100 kJ/mol, specifically more than about 120 kJ/mol, more specifically more than about 140 kJ/mol. In an embodiment, the absolute value of the Gibbs Free Energy of metal oxide formation of the fourth metal is about 100 to 2500 kJ/mol, specifically about 120 to about 2300 kJ/mol, more specifically about 140 to about 1900 kJ/mol.

The following Table 3 provides Gibbs free energy of metal oxide formation of representative metals.

TABLE 3

| Metal oxide | Δ_{f}G⁰ (kJ/mol) |
|---|---|
| Cu₂O | −146 |
| Ti₂O | −147.3 |
| RuO₄ | −152.2 |
| CdO | −228.7 |
| ZnO | −320.5 |
| Rh₂O₃ | −343 |
| K₂O₂ | −425.1 |
| Na₂O₂ | −447.7 |
| Ni₂O₃ | −489.5 |
| Bi₂O₃ | −493.7 |
| SnO | −515.8 |
| BaO | −520.3 |
| GeO₂ | −521.4 |
| Li₂O | −561.2 |
| SrO | −561.9 |
| MgO | −569.3 |
| BeO | −580.1 |
| PbO | −601.2 |
| CaO | 603.3 |
| MoO₃ | −668 |
| WO₃ | −764 |
| Co₃O₄ | −774 |
| In₂O₃ | −830.7 |
| SiO₂ | −856.3 |
| TiO₂ | −888.8 |
| Ga₂O₃ | −998.3 |
| Fe₃O₄ | −1015.4 |
| ZrO₂ | −1042.8 |
| Cr₂O₃ | −1058.1 |
| B₂O₃ | −1194.3 |
| Mn₃O₄ | −1283.2 |
| Al₂O₃ | −1582.3 |
| La₂O₃ | −1705.8 |
| Nd₂O₃ | −1720.8 |
| Nb₂O₅ | −1766 |
| V₃O₅ | −1803.3 |
| Y₂O₃ | −1816.6 |
| Sc₂O₃ | −1819.4 |
| Ti₃O₅ | −2317.4 |

The metallic glass may include an alloy of at least two metals of the first to fourth metals. Thus the at least two of the first to fourth metals that are included in the glass is selected from the first to the fourth metals. Accordingly, the metallic glass may have various combinations of the first to fourth metals. For example, when the first, the second, the third, and the fourth metals are respectively A, B, C, and D, the combination may include alloys of combinations such as A-B-C-D, A-B-C, A-B-D, A-C-D, B-C-D, A-B, A-C, A-D, B-C, B-D, or C-D.

In an embodiment, the metallic glass comprises two of the first to the fourth metals. In another embodiment, the metallic glass comprises three of the first to the fourth metals. In another embodiment, the metallic glass comprises each of the first to the fourth metals. In another embodiment, the metallic glass includes at least two of the first to the third metals; the second to the fourth metals; the first, third, and fourth metals; or the first, the second, and the fourth metals. Also, in each embodiment, the first to the fourth metals may be the same or different. Also, a metal of the conductive powder may be the same or different than each of the first to the fourth metals.

Herein, the first metal may be included to provide conductivity and may form an alloy with at least one selected from the second metal, the third metal, and the fourth metal.

The metallic glass may be at least one selected from, for example, Cu₅₀Zr₅₀, Cu₅₄Zr₂₂Ni₆Ti₁₈, Cu₄₈Zr₄₈Al₄, Cu₄₅Zr₄₅Ag₁₀, Cu₄₇Zr₄₅Al₄Ag₄, Cu₃₀Zr₄₈Al₈Ag₈Ni₆, Cu_{22.8}Zr_{61.4}Al_{9.9}Ag₁Fe_{4.95}, Cu₃₆Zr₄₆Al₈g₈Hf₂, Cu₃₀Ag₃₀Zr₃₀Ti₁₀, Ti₅₀Ni₁₅Cu₃₂Sn₃, Ti₄₅Ni₁₅Cu₂₅Sn₃Be₇Zr₅, Ni₆₀Nb₃₀Ta₁₀, Ni₆₁Zr₂₀Nb₇Al₄Ta₈, Ni_{57.5}Zr₃₅Al_{7.5}, Zr_{41.2}Ti_{13.8}Ni₁₀Cu_{12.5}Be_{22.5}, Mg₆₅Y₁₀Cu₁₅Ag₅Pd₅, Mn₅₅Al₂₅Ni₂₀, La₅₅Al₂₅Ni₁₀Cu₁₀, Mg₆₅Cu_{7.5}Ni_{7.5}Ag₅Zn₅Gd₁₀, Mg₆₅Cu₁₅Ag₁₀Y₆Gd₄, Fe₇₇Nb₆B₁₇, Fe₆₇Mo₁₃B₁₇Y₃, Ca₆₅Mg₁₅Zn₂₀, Ca_{66.4}Al_{33.6}, Mg₆₅CU₁₅Ag₁₀Gd₁₀, Mg₆₅CU₁₅Ag₁₀Gd₁₀, Mg₆₅CU₂₅Gd₁₀, Mg₆₅Cu₂₀Ag₅Y₁₀, Mg₆₅Cu₂₅Y₁₀, Mg₆₅Cu₁₅Ag₁₀Y₁₀, Cu₄₆Gd₄₇Al₇, Ca₆₀Mg₂₅Ni₁₅, Mg₆₅Cu₁₅Ag₅Pd₅Gd₁₀, Mg₇₀Ni₁₀Gd₂₀, Cu₄₆Y_{42.5}Al₇, Ti₅₅Zr₁₈Be₁₄Cu₇Ni₆, Ti₅₁Y₄Zr₁₈Be₁₄Cu₇Ni₆, Ti₄₀Zr₂₈Cu₉Ni₇Be₁₆, Ti₄₀Zr₂₅Ni₈Cu₉Be₁₈, Ti₄₉Nb₆Zr₁₈Be₁₄Cu₇Ni₆, Ti₅₀Zr₁₅Be₁₈Cu₉Ni₈, Ti₃₄Zr₃₁Cu₁₀Ni₈Be₁₇, Zr₃₆Ti₂₄Be₄₀, Ti₆₅Be₁₈Cu₉Ni₈, Zr₆₅Al_{7.5}Cu_{17.5}Ni₁₀, Zr₆₅Al_{7.5}Cu_{12.6}Ni₁₀Ag₅, Cu₅₀Zr₄₀Ti₁₀, Cu₃₀Ag₃₀Zr₃₀Ti₁₀, Ni₅₅Zr₁₂Al₁₁Y₂₂, and Cu₄₀Ni₅Ag₁₅Zr₃₀Ti₁₀, but is not limited thereto.

The organic vehicle may include an organic compound, an optional organic solvent, and optional additives known for use in the manufacture of conductive pastes for solar cells. The organic vehicle is combined with the conductive powder and the metallic glass primarily to provide a viscosity and rheology to the conductive paste effective for printing or coating the conductive paste. A wide variety of inert organic materials can be used, and can be selected by one of ordinary skill in the art without undue experimentation to achieve the desired viscosity and rheology, as well as other properties such as dispersibility of the conductive powder and the metallic glass, stability of conductive powder and the metallic glass and any dispersion thereof, drying rate, firing properties, and the like. Similarly, the relative amounts of the organic compound, any optional organic solvent, and any optional additive can be adjusted by one of ordinary skill in the art without undue experimentation in order to achieve the desired properties of the conductive paste.

The organic compound may be a polymer, for example, at least one selected from a C1 to C4 alkyl (meth)acrylate-based resin; a cellulose such as ethyl cellulose or hydroxyethyl cellulose; a phenolic resin; wood rosin; an alcohol resin; a halogenated polyolefin such as tetrafluoroethylene (e.g., TEFLON); and the monobutyl ether of ethylene glycol monoacetate.

The organic vehicle may further optionally include at least one additive selected from, for example, a surfactant, a thickener, and a stabilizer.

The solvent may be any solvent capable of dissolving or suspending the above other components of the conductive paste and may be, for example, at least one selected from terpineol, butylcarbitol, butylcarbitol acetate, pentanediol, dipentyne, limonene, an ethyleneglycol alkylether, a diethyleneglycol alkylether, an ethyleneglycol alkylether acetate, a diethyleneglycol alkylether acetate, a diethyleneglycol dialkylether acetate, a triethyleneglycol alkylether acetate, a triethylene glycol alkylether, a propyleneglycol alkylether, propyleneglycol phenylether, a dipropyleneglycol alkylether, a tripropyleneglycol alkylether, a propyleneglycol alkylether acetate, a dipropyleneglycol alkylether acetate, a tripropyleneglycol alkyl ether acetate, dimethylphthalic acid, diethylphthalic acid, dibutylphthalic acid, and desalted water.

The conductive powder, the metallic glass, and the organic vehicle may be included in an amount of about 30 to about 98 weight percent (wt %), about 1 to about 50 wt %, and about 69 to about 1 wt %, specifically about 40 to about 95 wt %, about 2 to about 40 wt %, and 58 to about 3 wt %, more specifically about 50 to about 90 wt %, about 4 to about 30 wt %, and about 46 to about 6 wt %, respectively, based on the total weight of the conductive paste.

The conductive paste is prepared by combining the components of the conductive paste by, for example, mechanical mixing. The conductive paste may be screen-printed to provide an electrode for an electronic device.

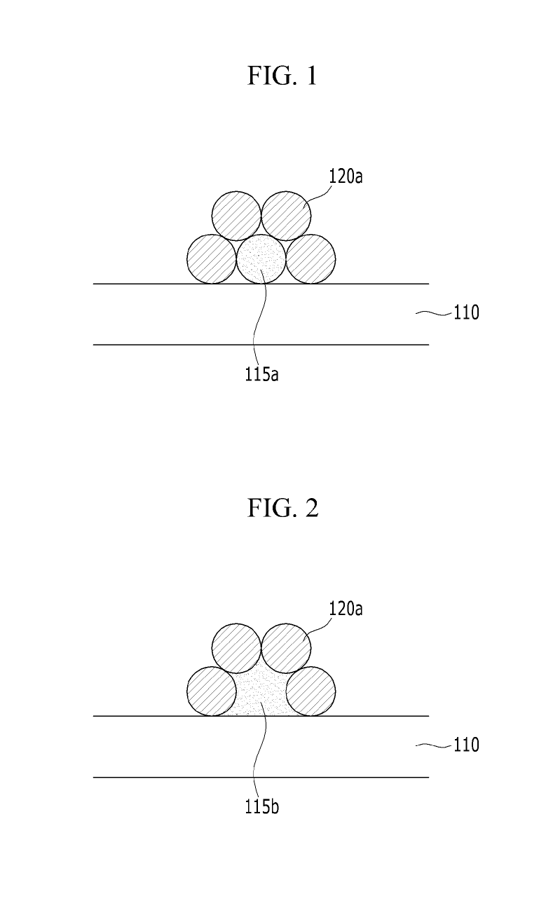

Hereinafter, illustrated is an electrode fabricated using the aforementioned conductive paste referring to FIGS. 1 to 4C.

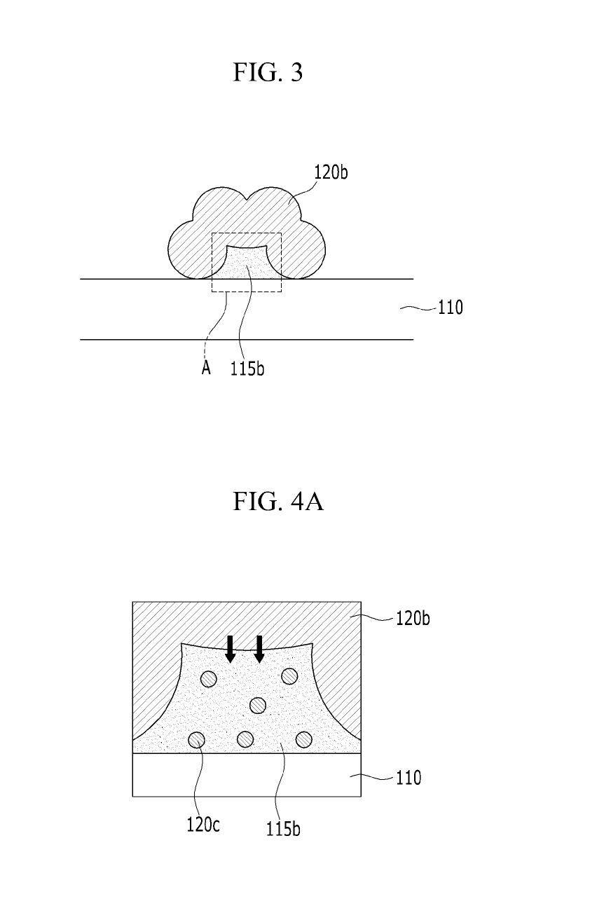

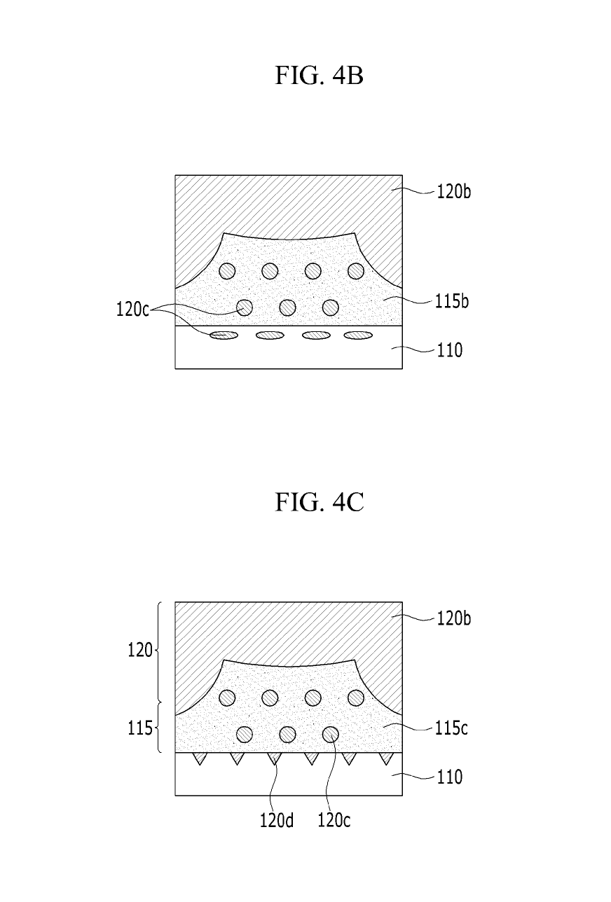

FIGS. 1 to 3 are a schematic diagram showing that when a conductive paste according to an embodiment is applied on a semiconductor substrate, a conductive powder and a metallic glass included therein are transformed due to heat and contact with the semiconductor substrate. FIGS. 4A to 4C are a schematic diagram enlarging region A of FIG. 3.

Referring to FIG. 1, a conductive paste including a conductive powder 120a and a metallic glass 115a is applied on a semiconductor substrate 110. The conductive powder 120a and the metallic glass 115a may each have the form of a particle having a spherical shape, for example.

Referring to FIG. 2, when the metallic glass 115a is heated to a first temperature higher than its glass transition temperature (“Tg”), the metallic glass 115a becomes soft and turns into a liquid-like metallic glass 115b. The first temperature may be about 1 to about 300° C., specifically about 5 to about 250° C., more specifically about 10 to about 200° C. higher than the Tg of the metallic glass. The liquid-like metallic glass 115b, which has a liquid-like properties, may fill a gap among a plurality of particles of the conductive powder 120a. Herein, the metallic glass 115a is first softened, because the glass transition temperature (“Tg”) of the metallic glass 115a is lower than the sintering temperature (“Ts”) of the conductive powder 120a.

Referring to FIG. 3, when a conductive paste is heated to a second temperature higher than the sintering temperature, the conductive powder 120a is sintered and particles of the conductive powder 120a closely bond with neighboring particles of conductive powder 120a to form a conductive powder agglomerate 120b. The second temperature may be about 1 to about 300° C., specifically about 5 to about 250° C., more specifically about 10 to about 200° C. higher than the Ts of the metallic glass.

As shown in FIGS. 2 and 3, the liquid-like metallic glass, which has liquid-like properties, is a supercooled liquid and wets a semiconductor substrate 110.

Referring to FIG. 4A, when the liquid-like metallic glass 115b is a supercooled liquid, some conductive particles 120c of the conductive powder agglomerate 120b diffuse into the liquid-like metallic glass 115b. As aforementioned, the liquid-like metallic glass 115b includes a component which can form a solid solution with the conductive powder agglomerate 120b.

In addition, as aforementioned, when a metallic glass has an extended supercooled liquid region, the liquid-like metallic glass 115b has a low viscosity and remains on and wets the semiconductor substrate 110. Accordingly, contact between the liquid-like metallic glass 115b and the semiconductor substrate 110 is improved.

Referring to FIG. 4B, when heated to a third temperature higher than the second temperature, conductive particles 120c diffuse into the liquid-like metallic glass 115b and permeate into the semiconductor substrate 110. The third temperature may be about 1 to about 300° C., specifically about 5 to about 250° C., more specifically about 10 to about 200° C. higher than the second temperature. Herein, as aforementioned, the liquid-like metallic glass 115b may have improved wetting properties and provide improved contact with the semiconductor substrate 110. Accordingly, the metallic glass may have a larger area in which conductive particles 120c permeate into the semiconductor substrate 110.

Referring to FIG. 4C, when the semiconductor substrate 110 is cooled down, conductive particles 120c permeated into the semiconductor substrate 110 crystallize to form crystallized conductive particles 120d at the surface of the semiconductor substrate 110. Also, the liquid-like metallic glass 115b may also crystallize to form a crystalline metallic glass 115c and the conductive particles 120c in the metallic glass may also crystallize.

In this way, the conductive powder agglomerate 120b may be made into an electrode 120. Also, a buffer layer 115 including the crystalline metallic glass 115c may be formed between the electrode 120 and the semiconductor substrate 110.

The crystallized conductive particles 120d in the buffer layer 115 and at the surface of the semiconductor substrate 110 effectively improve transfer of charges produced by solar light in the semiconductor substrate 110 to the electrode 120 and, simultaneously, decrease a contact resistance between the semiconductor substrate 110 and the electrode 120, thereby decreasing charge loss of a solar cell. Ultimately, the solar cell may have improved efficiency.

The electrode may be used as a conductive electrode for various other electronic devices.

A representative electronic device is a solar cell.

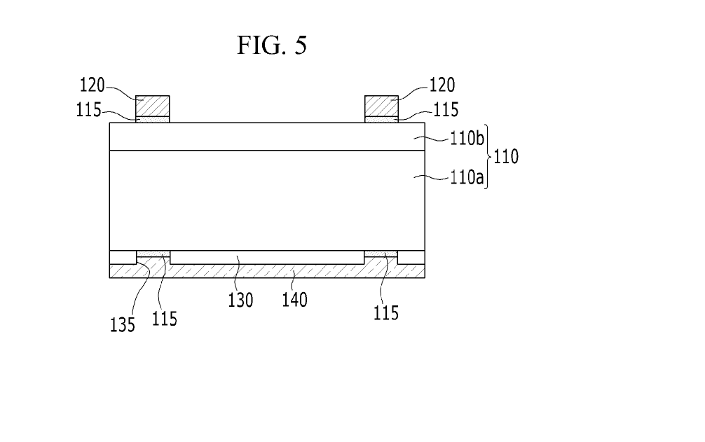

Referring to FIG. 5, a solar cell according to an embodiment is disclosed in further detail.

FIG. 5 is a cross-sectional view showing a solar cell according to an embodiment.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Hereinafter, positions of (or spatial relationships between) components will be described with respect to a semiconductor substrate 110 for better understanding and ease of description, but the disclosed embodiment is not limited thereto. In addition, for clarity of description, a solar energy incident side of a semiconductor substrate 110 is called a front side, and the opposite side is called a rear side, although alternative configurations are possible.

Referring to FIG. 5, a solar cell according to an embodiment may include a semiconductor substrate 110 including a lower semiconductor layer 110a and an upper semiconductor layer 110b.

The semiconductor substrate 110 may comprise a crystalline silicon or a compound semiconductor. The crystalline silicon may be, for example, a silicon wafer. One of the lower semiconductor layer 110a and the upper semiconductor layer 110b may be a semiconductor layer doped with a p-type impurity, and the other may be a semiconductor layer doped with an n-type impurity. For example, the lower semiconductor layer 110a may be a semiconductor layer doped with a p-type impurity, and the upper semiconductor layer 110b may be a semiconductor layer doped with an n-type impurity. Herein, the p-type impurity may be a Group III element such as boron (B), and the n-type impurity may be a Group V element such as phosphorus (P).

The surface of the upper semiconductor layer 110b may be textured, for example by surface texturing. The surface-textured upper semiconductor layer 110b may have protrusions and depressions, and may comprise a pyramidal shape, or may have a porous structure having a honeycomb shape, for example. The surface-textured upper semiconductor layer 110b may have an enhanced surface area to improve the light-absorption rate and decrease reflectivity, thereby improving efficiency of a solar cell.

A front electrode 120 is disposed (e.g., formed) on the upper semiconductor layer 110b. The front electrode 120 may be arranged in parallel to a direction of the substrate, and may have a grid pattern shape to reduce shadowing loss and sheet resistance.

The front electrode 120 may comprise a conductive material, for example a low resistivity conductive material such as silver (Ag).

The front electrode 120 may be disposed by a screen printing a conductive paste. The conductive paste is the same as described above.

A buffer layer 115 is disposed between the upper semiconductor layer 110b and the front electrode 120 by heat treating the conductive paste disposed to form the front electrode 120. The buffer layer 115 may be conductive due to inclusion of the metallic glass. Because the buffer layer 115 has portions that contact the electrode 120 and the upper semiconductor layer 110b, it may decrease loss of electric charges by enlarging the effective path for transferring electric charges between the upper semiconductor layer 110b and the front electrode 120. The buffer layer may also reduce resistive losses, for example.

The metallic glass of the buffer layer 115 is derived from the conductive paste used to form the front electrode 120. The metallic glass may melt before the conductive material of the front electrode 120 during processing, so that the metallic glass is disposed under the front electrode 120 to form the buffer layer.

A bus bar electrode (not shown) may be disposed on the front electrode 120. The bus bar electrode can connect adjacent solar cells of a plurality of solar cells.

A dielectric layer 130 may be formed under the semiconductor substrate 110. The dielectric layer 130 may increase efficiency of a solar cell by substantially or effectively preventing recombination of electric charges and leaking of electric current. The dielectric layer 130 may include a penetration part 135 (e.g., a through hole), and the semiconductor substrate 110 and a rear electrode 140 that will be further described below may contact through the penetration part 135.

The dielectric layer 130 may comprise at least one selected from silicon oxide (SiO₂), silicon nitride (SiNₓ), aluminum oxide (Al₂O₃, and may have a thickness of about 100 to about 2000 angstroms (Å), specifically about 200 to about 1800 Å, more specifically about 300 to about 1600 Å.

A rear electrode 140 is disposed under the dielectric layer 130. The rear electrode 140 may comprise a conductive material, and the conductive material may be an opaque metal such as aluminum (Al). The rear electrode 140 may be disposed by screen printing a conductive paste in the same manner as the front electrode 120.

In an embodiment, a buffer layer 115 is disposed between the rear electrode 140 and the lower semiconductor layer 110a in the same manner as the front electrode 120. In another embodiment, the buffer layer is disposed between the rear electrode 140 and the lower semiconductor layer 110a or between the front electrode 120 and the upper semiconductor layer 110b.

Hereinafter, a method of manufacturing the solar cell is further described with reference to FIG. 5.

First, a semiconductor substrate 110, such as a silicon wafer, is prepared. The semiconductor substrate 110 may be doped with an impurity, such as a p-type impurity, as an example.

Then the semiconductor substrate 110 may be subjected to a surface texturing treatment. The surface-texturing treatment may be performed by a wet method using at least one strong acid selected from, for example, nitric acid, hydrofluoric acid, and the like, or at least one strong base selected from, for example, sodium hydroxide and the like; or the surface-texturing treatment may be performed by a dry method such as plasma treatment.

Then, the semiconductor substrate 110 may be doped with an n-type impurity, for example. The n-type impurity may be doped by diffusing at least one selected from, for example, POCl₃, H₃PO₄, and the like at a high temperature. The semiconductor substrate 110 includes a lower semiconductor layer 110a and an upper semiconductor layer 110b doped with different impurities than each other.

Then a conductive paste for a front electrode is applied on the upper semiconductor layer 110b. The conductive paste for a front electrode may be applied by a screen printing method. The screen printing method includes applying the conductive paste, which comprises a conductive powder, a metallic glass, and an organic vehicle at a location where a front electrode is disposed, and drying the same.

As further disclosed above, the conductive paste may include a metallic glass, and the metallic glass may be prepared using any suitable method such as melt spinning, infiltration casting, gas atomization, ion irradiation, or mechanical alloying.

Then the conductive paste for a front electrode may be dried.

A dielectric layer 130 may be provided by disposing (e.g., stacking, forming, or depositing) aluminum oxide (Al₂O₃) or silicon oxide (SiO₂) on an entirety of or on a portion of a rear side of the semiconductor substrate 110. The dielectric layer 130 may be disposed by a plasma enhanced chemical vapor deposition (“PECVD”) method, for example.

Then a penetration part 135 may be provided on a portion of the dielectric layer 130 by ablation with a laser, for example.

The conductive paste for a rear electrode is subsequently applied on a side of the dielectric layer 130, which in an embodiment is opposite the semiconductor substrate 110, by a screen printing method.

Then, a conductive paste for a rear electrode is dried.

Next, the conductive paste for a front electrode and the conductive paste for a rear electrode are co-fired (e.g., heat treated), or fired individually. Thus the conductive paste for a front electrode and the conductive paste for a rear electrode may be fired in the same or in different processes.

The firing may be performed in a furnace and at a temperature higher than the melting temperature of the conductive metal, for example at a temperature ranging from about 400° C. to about 1000° C., specifically about 450° C. to about 950° C., more specifically about 500° C. to about 900° C.

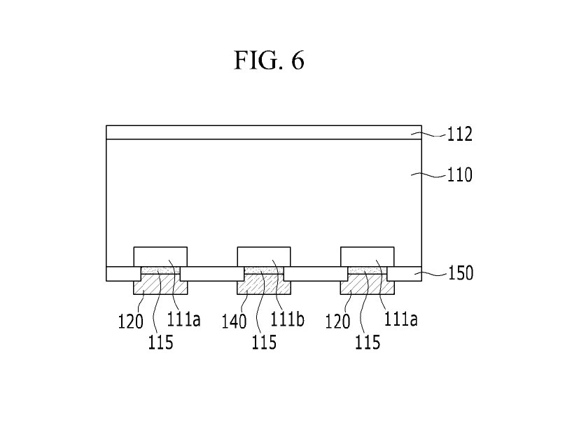

Hereinafter, a solar cell according to another embodiment is disclosed referring to FIG. 6.

FIG. 6 is a cross-sectional view showing a solar cell according to another embodiment.

A solar cell may include a semiconductor substrate 110 doped with a p-type or an n-type impurity. The semiconductor substrate 110 may include a first doping region 111a and second doping region 111b that are provided on the rear side of the semiconductor substrate 110, and are doped with different impurities than each other. For example, the first doping region 111a may be doped with an n-type impurity, and the second doping region 111b may be doped with a p-type impurity. The first doping region 111a and the second doping region 111b may be alternately disposed on the rear side of the semiconductor substrate 110.

The front side of the semiconductor substrate 110 may be surface-textured, and therefore may enhance the light-absorption rate and decrease the reflectivity of the solar cell, thereby improving efficiency of the solar cell. An insulation layer 112 is provided on the semiconductor substrate 110. The insulation layer 112 may comprise an insulating material that is substantially transparent and thus absorbs little light, for example at least one selected from silicon nitride (SiNₓ), silicon oxide (SiO₂), titanium oxide (TiO₂), aluminum oxide (Al₂O₃), magnesium oxide (MgO), and cerium oxide (CeO₂). The insulation layer 112 may be a single layer or more than one layer. The insulation layer 112 may have a thickness ranging from about 200 to about 1500 Å, specifically 300 to about 1400 Å, more specifically about 400 to about 1300 Å.

The insulation layer 112 may be an anti-reflective coating (“ARC”) that decreases the reflectivity of light and increases selectivity of a particular wavelength region on the surface of the solar cell, and simultaneously improves properties of silicon on the surface of the semiconductor substrate 110, thereby increasing efficiency of the solar cell.

A dielectric layer 150 including first and second penetration parts may be disposed on the rear side of the semiconductor substrate 110.

The front electrode 120 electrically connected with the first doping region 111a and the rear electrode 140 electrically connected with the second doping region 111b are disposed on the rear side of the semiconductor substrate 110, respectively. The front electrode 120 and the first doping region 111a may be contacted through the first penetration part, and the rear electrode 140 and the second doping region 111b may be in contact through the second penetration part. The front electrode 120 and the rear electrode 140 may be alternately disposed.

As disclosed in the above embodiment, the front electrode 120 and the rear electrode 140 may be disposed using a conductive paste including a conductive powder, a metallic glass, and an organic vehicle, which is the same as described above.

A buffer layer 115 is disposed between the first doping region 111a and the front electrode 120, or between the second doping region 111b and the rear electrode 140. The buffer layer 115 may be electrically conductive due inclusion of a metallic glass. Because the buffer layer 115 includes portions contacting either the front electrode 120 or the rear electrode 140, and portions contacting either the first doping region 111a or the second doping region 111b, respectively, loss of electric charge may be decreased by enlarging or otherwise improving the path for transferring electric charge between the first doping region 111a and the front electrode 120, or between the second doping region 111b and the rear electrode 140. In addition, the buffer layer 115 may substantially or effectively prevent a material of the front electrode 120 or the rear electrode 140 from diffusing into the first or second doping regions 111a or 111b, respectively.

A solar cell according to the embodiment including both of the front electrode 120 and the rear electrode 140 on the rear surface of the solar cell may decrease an area where a metal is disposed on the front surface. This may decrease shadowing loss and increase solar cell efficiency.

Hereinafter, the method of manufacturing a solar cell will be further disclosed referring to FIG. 6.

First, a semiconductor substrate 110 doped with, for example, an n-type impurity is prepared. Then, the semiconductor substrate 110 is surface-textured, and insulation layer 112 and dielectric layer 150 are disposed on a front side and a rear side of the semiconductor substrate 110, respectively. The insulation layer 112 and the dielectric layer 150 may be provided by chemical vapor deposition (“CVD”), for example.

Then, the first doping region 111a and the second doping region 111b may be disposed by sequentially doping a p-type impurity and an n-type impurity at a high concentration in the rear side of the semiconductor substrate 110.

Then, a conductive paste for a front electrode is applied on a portion (e.g. on a side) of the dielectric layer 150 corresponding to the first doping region 111a, and a conductive paste for a rear electrode is applied a portion of the dielectric layer 150 corresponding to the second doping region 111b. The conductive paste for the front electrode and the conductive paste for the rear electrode may be disposed by screen printing, for example, and the conductive paste may comprise a conductive powder, a metallic glass, and an organic vehicle.

Next, the conductive paste for the front electrode and the conductive paste for the rear electrode may be fired together or separately. The firing (e.g., heat treating) may be performed in a furnace at a temperature higher than the melting temperature of a conductive metal.

Herein, the conductive paste is applied to provide an electrode for a solar cell, but the conductive paste may also be used to provide an electrode for various other electronic devices such as a plasma display panel (“POP”), a liquid crystal display (“LCD”), or an organic light emitting diode (“OLED”).

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A conductive paste comprising in combination:
a conductive powder,
a metallic glass, and
an organic vehicle,
wherein the metallic glass comprises an alloy of at least two metals selected from
a first metal having a low resistivity,
a second metal which forms a solid solution with the conductive powder,
a third metal which extends a supercooled liquid region of the metallic glass, and
a fourth metal having a higher standard free energy of formation of oxide than a standard free energy of formation of oxide of each of the first, the second, and the third metals if present.

2. The conductive paste of claim 1, wherein the first metal has a resistivity of less than about 100 microohm-centimeters.

3. The conductive paste of claim 1, wherein the first metal has a resistivity of less than about 15 microohm-centimeters.

4. The conductive paste of claim 1, wherein the first metal is at least one selected from silver, copper, gold, aluminum, calcium, beryllium, magnesium, sodium, molybdenum, tungsten, tin, zinc, nickel, potassium, lithium, iron, palladium, platinum, rubidium, chromium, and strontium Sr).

5. The conductive paste of claim 1, wherein the second metal has a heat of mixing with the conductive powder of less than 0 KJ/mol.

6. The conductive paste of claim 5, wherein the conductive powder comprises silver, and
the second metal is at least one selected from lanthanum, cerium, praseodymium, promethium, samarium, lutetium, yttrium, neodymium, gadolinium, terbium, dysprosium, holmium, erbium, thulium, thorium, calcium, scandium, barium, ytterbium, strontium, europium, zirconium, lithium, hafnium, magnesium, phosphorus, arsenic, palladium, gold, plutonium, gallium, germanium, aluminum, zinc, antimony, silicon, tin, titanium, cadmium, indium, platinum, and mercury.

7. The conductive paste of claim 1, wherein the third metal reduces a glass transition temperature of the metallic glass or increases a crystallization temperature of the metallic glass.

8. The conductive paste of claim 1, wherein the third metal reduces a glass transition temperature of the metallic glass and increases a crystallization temperature of the metallic glass.

9. The conductive paste of claim 7, wherein the metallic glass comprises copper and zirconium, and
the third metal is at least one selected from aluminum, silver, nickel, titanium, iron, and hafnium.

10. The conductive paste of claim 1, wherein the third metal is included in an amount of about 10 atomic percent or less, based on a total amount of the metallic glass.

11. The conductive paste of claim 1, wherein the metallic glass has a supercooled liquid region of about 5° C. to about 200° C.

12. The conductive paste of claim 1, wherein the supercooled region is within a temperature range of about 100° C. to about 800° C.

13. The conductive paste of claim 1, wherein the fourth metal has an absolute value of a Gibbs free energy of metal oxide formation greater than an absolute value of a Gibbs free energy of metal oxide formation of each of the first, the second, and the third metals if present.

14. The conductive paste of claim 13, wherein the fourth metal has an absolute value of a Gibbs free energy of metal oxide formation of about 100 kiloJoules per mole or greater.

15. The conductive paste of claim 1, wherein the conductive powder, the metallic glass, and the organic vehicle are included in an amount of about 30 to about 98 weight percent, about 1 to about 50 weight percent, and about 69 to about 1 weight percent, respectively, based on a total weight of the conductive paste.

16. The conductive paste of claim 1, wherein the metallic glass is substantially amorphous.

17. An electronic device comprising,
an electrode comprising a fired conductive paste comprising a combination of a conductive powder, a metallic glass, and an organic vehicle,
wherein the metallic glass comprises an alloy of at least two metals selected from
a first metal having a low resistivity,
a second metal which forms a solid solution with the conductive powder,
a third metal which extends a supercooled liquid region of the metallic glass, and
a fourth metal having a higher standard free energy of formation of oxide than a standard free energy of formation of oxide of each of the first, the second, and the third metals, if present.

18. The electronic device of claim 17, wherein the first metal has a resistivity of less than about 100 microohm-centimeters, and
the second metal has a heat of mixing with the conductive powder of less than 0 kJ/mol.

19. The electronic device of claim 17, wherein the third metal reduces a glass transition temperature of the metallic glass or increases a crystallization temperature of the metallic glass, and
the fourth metal has an absolute value of a Gibbs free energy of metal oxide formation greater than an absolute value of a Gibbs free energy of metal oxide formation of each of the first, the second, and the third metals, if present.

20. A solar cell comprising
a semiconductor layer, and
an electrode electrically connected with the semiconductor layer and comprising a fired conductive paste comprising a combination of a conductive powder, a metallic glass, and an organic vehicle,
wherein the metallic glass comprises an alloy of at least two metals selected from
a first metal having a low resistivity,
a second metal which forms a solid solution with the conductive powder,
a third metal which extends a supercooled liquid region of the metallic glass, and
a fourth metal having a higher standard free energy of formation of oxide than a standard free energy of formation of oxide of each of the first, the second, and the third metals if present.

21. The solar cell of claim 20, wherein the first metal has resistivity of less than about 100 microohm-centimeters, and
the second metal has a heat of mixing with the conductive powder of less than 0 kJ/mol.

22. The solar cell of claim 21, wherein the first metal is at least one selected from silver, copper, gold, aluminum, calcium, beryllium, magnesium, sodium, molybdenum, tungsten, tin, zinc, nickel, potassium, lithium, iron, palladium, platinum, rubidium, chromium, and strontium.

23. The solar cell of claim 21, wherein the conductive powder comprises silver, and
the second metal is at least one selected from lanthanum, cerium, praseodymium, promethium, samarium, lutetium, yttrium, neodymium, gadolinium, terbium, dysprosium, holmium, erbium, thulium, thorium, calcium, scandium, barium, ytterbium, strontium, europium, zirconium, lithium, hafnium, magnesium, phosphorus, arsenic, palladium, gold, plutonium, gallium, germanium, aluminum, zinc, antimony, silicon, tin, titanium, cadmium, indium, platinum, and mercury.

24. The solar cell of claim 20, wherein the third metal reduces a glass transition temperature of the metallic glass or increases a crystallization temperature of the metallic glass, and
the fourth metal has an absolute value of Gibbs free energy of metal oxide formation greater than an absolute value of Gibbs free energy of metal oxide formation of each of the first, the second, and the third metals, if present.

25. A solar cell comprising
a semiconductor layer, and
an electrode comprising a conductive material and electrically connected with the semiconductor layer, and
a buffer layer contacting the semiconductor layer and the electrode, wherein the buffer layer comprises an alloy of at least two metals selected from
a first metal having a low resistivity,
a second metal which forms a solid solution with a conductive powder,
a third metal which extends a supercooled liquid region of a metallic glass of the buffer layer, and
a fourth metal having a higher standard free energy of formation of oxide than a standard free energy of formation of oxide of each of the first, the second, and the third metals if present.

26. The solar cell of claim 25, wherein the buffer layer further comprises a crystallized conductive material.

27. The solar cell of claim 25, wherein the conductive material is included in at least one of the semiconductor layer and the buffer layer.

28. The solar cell of claim 25, wherein the first metal has resistivity of less than about microohm-centimeters, and the second metal may have a heat of mixing with the conductive powder of less than 0 kJ/mol.

29. The solar cell of claim 28, wherein the first metal is at least one selected from silver, copper, gold, aluminum, calcium, beryllium, magnesium, sodium, molybdenum, tungsten, tin, zinc, nickel, potassium, lithium, iron, palladium, platinum, rubidium, chromium, and strontium.

30. The solar cell of claim 25, wherein the conductive powder comprises silver, and
the second metal is at least one selected from lanthanum, cerium, praseodymium, promethium, samarium, lutetium, yttrium, neodymium, gadolinium, terbium, dysprosium, holmium, erbium, thulium, thorium, calcium, scandium, barium, ytterbium, strontium, europium, zirconium, lithium, hafnium, magnesium, phosphorus, arsenic, palladium, gold, plutonium, gallium, germanium, aluminum, zinc, antimony, silicon, tin, titanium, cadmium, indium, platinum, and mercury.

31. The solar cell of claim 25, wherein the third metal reduces a glass transition temperature of the metallic glass or increases a crystallization temperature of the metallic glass, and
the fourth metal has an absolute value of a Gibbs free energy of metal oxide formation greater than an absolute value of a Gibbs free energy of metal oxide formation of each of the first, the second, and the third metals, if present.
